(19) United States
(12) Patent Application Publication
(10) Pub. No.: US 2024/0313507 A1
(43) Pub. Date: Sep. 19, 2024

(54) VERTICAL CAVITY SURFACE EMITTING LASER DEVICE, VERTICAL CAVITY SURFACE EMITTING LASER DEVICE ARRAY, AND METHOD OF PRODUCING A VERTICAL CAVITY SURFACE EMITTING LASER DEVICE

(71) Applicant: SONY GROUP CORPORATION, TOKYO (JP)

(72) Inventors: TATSUSHI HAMAGUCHI, TOKYO (JP); RINTARO KODA, TOKYO (JP); EIJI NAKAYAMA, KUMAMOTO (JP); HIDEKAZU KAWANISHI, TOKYO (JP); KENTARO HAYASHI, TOKYO (JP)

(21) Appl. No.: 18/577,289

(22) PCT Filed: Mar. 9, 2022
(86) PCT No.: PCT/JP2022/010251

§ 371 Date: Jan. 8, 2024

(30) Foreign Application Priority Data
Jul. 19, 2021 (JP) 2021-118837

(51) Int. Cl. H01S 5/183

(52) U.S. Cl. CPC H01S 5/18361; H01S 5/18305

(57) ABSTRACT

[Solving Means] A vertical cavity surface emitting laser device according to the present technology includes: a semiconductor layer; a substrate; a first mirror; and a second mirror. The semiconductor layer includes an active layer formed of a first material. The substrate is bonded to the semiconductor layer, is formed of a second material having bandgap energy higher than that of the first material, and causes light of a specific wavelength to be transmitted therethrough. The first mirror is provided on a side of the semiconductor layer opposite to the substrate, and reflects the light of a specific wavelength. The second mirror is provided on a side of the substrate opposite to the semiconductor layer, and reflects the light of a specific wavelength.

### TECHNICAL FIELD

The present technology relates to a vertical cavity surface emitting laser device that is a semiconductor laser device, a vertical cavity surface emitting laser device array, and a method of producing the vertical cavity surface emitting laser device.

### BACKGROUND ART

A vertical cavity surface emitting laser (VCSEL) device is a type of semiconductor laser device, and is a device that resonates light in a direction perpendicular to a substrate surface and emits laser light in the same direction.

In general, as a structure of the VCSEL device, a post mesa structure as disclosed in the following Patent Literature 1 is used. In this structure, a circular post mesa having a diameter of approximately 30 μm is formed by a method such as dry etching, and a current confinement structure is formed by selective oxidation of AlGaAs or AlAs with a high Al composition. The supplied current is injected into an active layer with high efficiency by the current confinement structure. Further, since the refractive index of the selectively oxidized region is reduced to approximately half, an effect equivalent to that of a lens can be achieved and diffraction loss is reduced, making it possible to confine light. It has excellent productivity, and is beginning to become widespread, e.g., it is introduced into smartphones.

### CITATION LIST

### Patent Literature

Patent Literature 1: Japanese Patent Application Laid-open No. 2001-210908

### DISCLOSURE OF INVENTION

### Technical Problem

Meanwhile, research activities on VCSEL devices using GaN have become active in recent years, and blue-emitting VCSEL device and green-emitting VCSEL device using GaN have been known in previous research. In the case of using a VCSEL device for display purposes, a red-emitting VCSEL device that oscillates in a wavelength band of a wavelength of 650 nm or less is necessary. In order to allow the crystal of an active layer that can be used in the red-emitting VCSEL device to grow on a GaN substrate, it is necessary to allow an InGaN layer with a high In composition to grow, which is technically difficult.

For this reason, a VCSEL device formed on a GaAs substrate is being studied. However, the VCSEL device formed on a GaAs substrate has a problem that output decreases at high temperatures, because carrier overflow is likely to occur and heat dissipation is insufficient.

In view of the circumstances as described above, it is an object of the present technology to provide a vertical cavity surface emitting laser device that is formed using a GaAs substrate and is suitable for higher output, a vertical cavity surface emitting laser device array, and a method of producing the vertical cavity surface emitting laser device.

### Solution to Problem

In order to achieve the above-mentioned object, a vertical cavity surface emitting laser device according to an embodiment of the present technology includes: a semiconductor layer; a substrate; a first mirror; and a second mirror.

The semiconductor layer includes an active layer formed of a first material.

The substrate is bonded to the semiconductor layer, is formed of a second material having bandgap energy higher than that of the first material, and causes light of a specific wavelength to be transmitted therethrough.

The first mirror is provided on a side of the semiconductor layer opposite to the substrate, and reflects the light of a specific wavelength.

The second mirror is provided on a side of the substrate opposite to the semiconductor layer, and reflects the light of a specific wavelength.

The second material may be a material different from the first material in group V.

The first material may be AlGaAs, GaAs, InGaAs, InGaP, AlInGaP, AlGaInAs, or GaInAsP.

The second material may be GaN.

The second material may be a material having a thermal conductivity higher than that of the first material.

An energy level difference between the first material and the second material is 100 meV or more.

The first material and the second material may have different crystal structures.

The second mirror may be a concave mirror whose surface on a side of the substrate is a concave surface.

The vertical cavity surface emitting laser device may have a current confinement structure formed by ion implantation, oxidation confinement, or a buried tunnel junction.

The semiconductor layer may further include a spacer layer located between the active layer and the substrate, and
a thickness of the spacer layer may be 10 nm or more and 1000 nm or less.

The first mirror and the second mirror may each be a DBR (Distributed Bragg Reflector), a metal mirror, or a diffraction grating.

The DBR may be a dielectric DBR formed of a dielectric or a semiconductor DBR formed of a semiconductor.

In the vertical cavity surface emitting laser device, laser light may be transmitted through first mirror or the second mirror and emitted.

In order to achieve the above-mentioned object, in a vertical cavity surface emitting laser device array according to an embodiment of the present technology, a plurality of vertical cavity surface emitting laser devices is arrayed, each of the vertical cavity surface emitting laser devices including a semiconductor layer, a substrate, a first mirror, and a second mirror.

The semiconductor layer includes an active layer formed of a first material.

The substrate is bonded to the semiconductor layer, is formed of a second material having bandgap energy higher than that of the first material, and causes light of a specific wavelength to be transmitted therethrough.

The first mirror is provided on a side of the semiconductor layer opposite to the substrate, and reflects the light of a specific wavelength.

The second mirror is provided on a side of the substrate opposite to the semiconductor layer, and reflects the light of a specific wavelength.

In order to achieve the above-mentioned object, a method of producing a vertical cavity surface emitting laser device according to an embodiment of the present technology includes: bonding a semiconductor layer that includes an active layer formed of a first material and a substrate that is formed of a second material having bandgap energy higher than that of the first material and causes light of a specific wavelength to be transmitted therethrough to each other to form a structure including the semiconductor layer, the substrate, a first mirror that is provided on a side of the semiconductor layer opposite to the substrate and reflects the light of a wavelength, and a second mirror that is provided on a side of the substrate opposite to the semiconductor layer and causes the light of a wavelength to be transmitted therethrough.

### BRIEF DESCRIPTION OF DRAWINGS

FIG. 1 is a cross-sectional view of a VCSEL device according to an embodiment of the present technology.

FIG. 2 is a schematic exploded view of the VCSEL device.

FIG. 3 is a plan view of the VCSEL device.

FIG. 4 is a cross-sectional view of a semiconductor layer included in the VCSEL device.

FIG. 5 is a band diagram showing energy bands of an active layer and a substrate included in the VCSEL device.

FIG. 6 is a cross-sectional view of the VCSEL device bonded to a support substrate.

FIG. 7 is a schematic diagram showing an operation of the VCSEL element.

FIG. 8 is a band diagram showing an operation of the VCSEL device.

FIG. 9 is a band diagram showing an example of calculating band alignment of the VCSEL device.

FIG. 10 is a schematic diagram showing a method 1 of producing the VCSEL device.

FIG. 11 is a schematic diagram showing the method 1 of producing the VCSEL device.

FIG. 12 is a schematic diagram showing the method 1 of producing the VCSEL device.

FIG. 13 is a schematic diagram showing the method 1 of producing the VCSEL device.

FIG. 14 is a schematic diagram showing the method 1 of producing the VCSEL device.

FIG. 15 is a schematic diagram showing the method 1 of producing the VCSEL device.

FIG. 16 is a schematic diagram showing the method 1 of producing the VCSEL device.

FIG. 17 is a schematic diagram showing a method 2 of producing the VCSEL device.

FIG. 18 is a schematic diagram showing the method 2 of producing the VCSEL device.

FIG. 19 is a schematic diagram showing the method 2 of producing the VCSEL device.

FIG. 20 is a schematic diagram showing the method 2 of producing the VCSEL device.

FIG. 21 is a schematic diagram showing the method 2 of producing the VCSEL device.

FIG. 22 is a schematic diagram showing a method 3 of producing the VCSEL device.

FIG. 23 is a schematic diagram showing the method 3 of producing the VCSEL device.

FIG. 24 is a schematic diagram showing the method 3 of producing the VCSEL device.

FIG. 25 is a schematic diagram showing the method 3 of producing the VCSEL device.

FIG. 26 is a schematic diagram showing the method 3 of producing the VCSEL device.

FIG. 27 is a schematic diagram showing the method 3 of producing the VCSEL device.

FIG. 28 is a schematic diagram showing the method 3 of producing the VCSEL device.

FIG. 29 is a schematic diagram showing the method 3 of producing the VCSEL device.

FIG. 30 is a schematic diagram showing the method 3 of producing the VCSEL device.

FIG. 31 is a schematic diagram showing the method 3 of producing the VCSEL device.

FIG. 32 is a cross-sectional view of a VCSEL device according to a modified example of the present technology.

FIG. 33 is a cross-sectional view of a VCSEL device according to a modified example of the present technology.

FIG. 34 is a cross-sectional view of a VCSEL device according to a modified example of the present technology.

### MODE(S) FOR CARRYING OUT THE INVENTION

A vertical cavity surface emitting laser (VCSEL) device according to an embodiment of the present technology will be described.

### [Configuration of VCSEL Device]

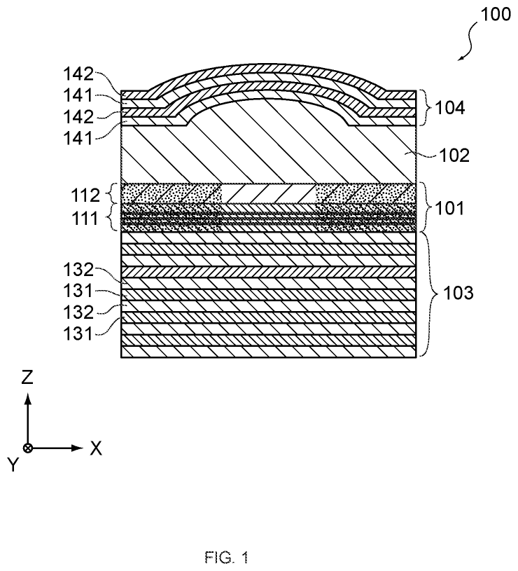

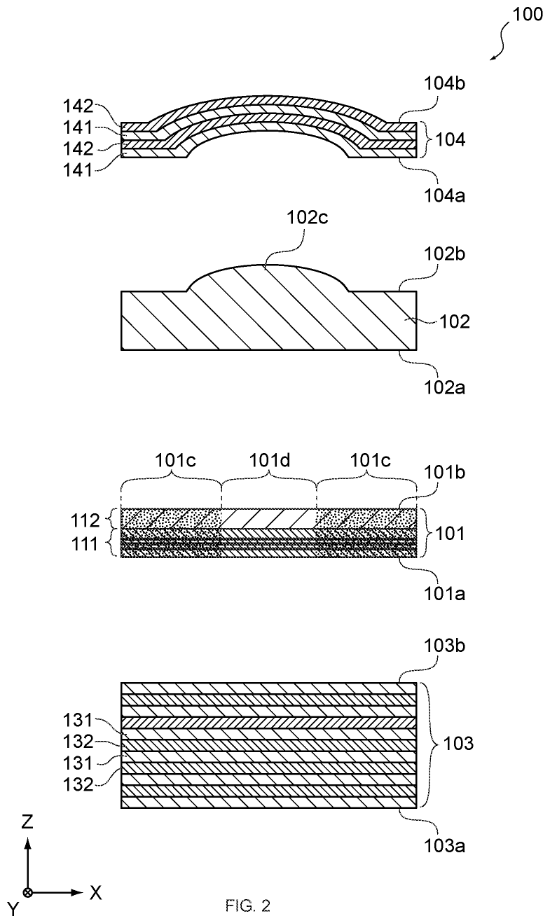

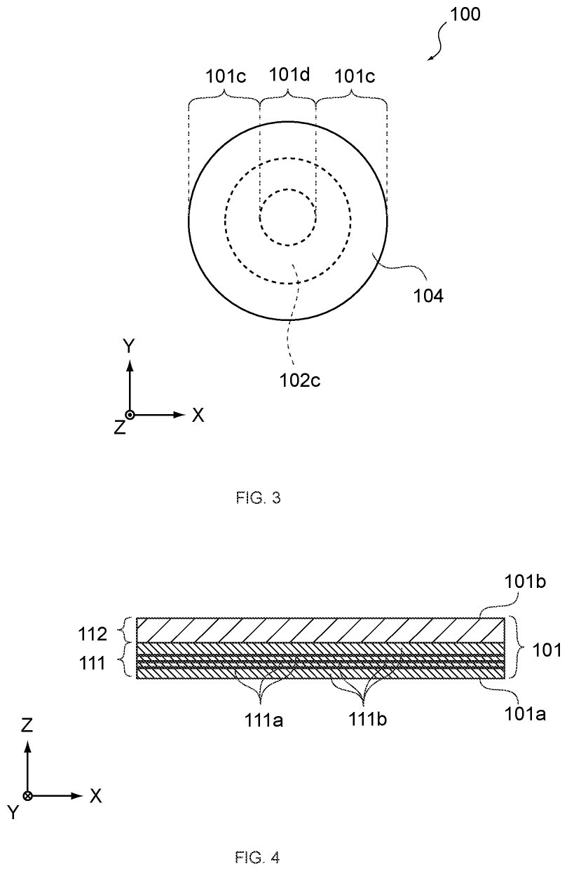

FIG. 1 is a schematic diagram showing a cross-sectional view of a VCSEL device 100 according to this embodiment, and FIG. 2 is an exploded view of the VCSEL device 100. FIG. 3 is a plan view of the VCSEL device 100. As shown in these figures, the VCSEL device 100 includes a semiconductor layer 101, a substrate 102, a first mirror 103, and a second mirror 104.

The semiconductor layer 101 is a layer that generates laser oscillation, and includes a first main surface 101a, a second main surface 101b, an ion implantation region 101c, and a non-ion-implantation region 101d as shown in FIG. 2. The first main surface 101a is a main surface on the side of the first mirror 103. The second main surface 101b is a main surface opposite to the first main surface 101a, and is a main surface on the side of the substrate 102. FIG. 4 is a schematic diagram of the semiconductor layer 101, in which the ion implantation region 101c and the non-ion-implantation region 101d are not shown. As shown in the figure, the semiconductor layer 101 includes an active layer 111 and a spacer layer 112.

The active layer 111 is a layer on the side of the first main surface 101a in the semiconductor layer 101. The active layer 111 is formed of a first material and emits and amplifies spontaneous emission light by carrier recombination. The first material is a material whose crystal is capable of growing on a GaAs substrate. Specific examples thereof include AlGaAs, GaAs, InGaAs, InGaP, AlInGaP, AlGaInAs, and GaInAsP.

The active layer 111 includes a quantum well layer 111a having small bandgap energy and a barrier layer 111b having large bandgap energy that are alternately stacked to include a plurality of layers. The quantum well layer 111a and the barrier layer 111b are each formed of one or more of the above materials. In the case where the active layer 111 is formed of a plurality of types of materials, the material having the largest band gap energy is used as the first material.

The spacer layer 112 is a layer on the side of the second main surface 101b in the semiconductor layer 101. The spacer layer 112 is located between the active layer 111 and the substrate 102, and adjusts the distance between the first mirror 103 and the second mirror 104. The spacer layer 112 is formed of GaAs. The thickness of the spacer layer 112 is suitably 10 nm or more and 1000 nm or less.

The ion implantation region 101c (see FIG. 2) is a region of the semiconductor layer 101 into which ions such as boron are implanted, and insulated by ion implantation. As shown in FIG. 3, the ion implantation region 101c is provided on the outer periphery side of the semiconductor layer 101, and surrounds the non-ion-implantation region 101d in the layer surface direction (X-Y direction). The non-ion-implantation region 101d is a region of the semiconductor layer 101 into which ions are not implanted. As shown in FIG. 2, the non-ion-implantation region 101d is provided on the inner peripheral side of the semiconductor layer 101, and is surrounded by the non-ion-implantation region 101d in the layer surface direction (X-Y direction). A current flowing through the semiconductor layer 101 cannot pass through the ion implantation region 101c and concentrates on the non-ion-implantation region 101d. That is, the ion implantation region 101c and the non-ion-implantation region 101d form a current confinement structure.

The substrate 102 is bonded to the semiconductor layer 101, and includes a first main surface 102a, a second main surface 102b, and a lens 102c as shown in FIG. 2. The first main surface 102a is a main surface on the side of the semiconductor layer 101, and is bonded to the second main surface 101b of the semiconductor layer 101. The second main surface 102b is a main surface opposite to the first main surface 102a, and is a main surface on the side of the second mirror 104. The lens 102c protrudes toward the second mirror 104, and forms a curved surface on the second main surface 102b. The substrate 102 causes light of a specific wavelength to be transmitted therethrough. This specific wavelength is the oscillation wavelength of the VCSEL device 100 described below (hereinafter, a wavelength λ).

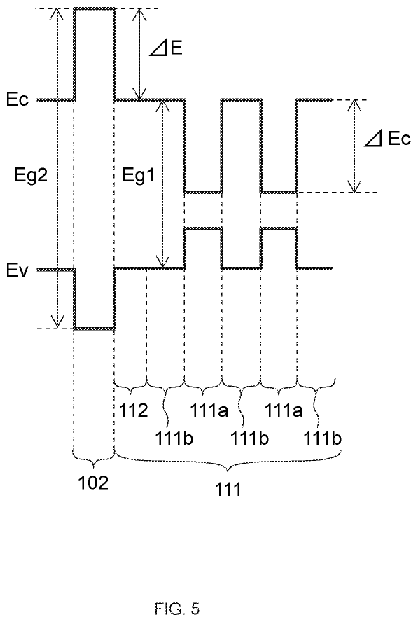

Further, the substrate 102 is formed of a second material having bandgap energy higher than that of the first material that is the material of the active layer 111. FIG. 5 is a band diagram showing energy bands of the active layer 111 and the substrate 102, and the difference between a conductor (Ev) and a valence body (Ec) indicates bandgap energy. In the figure, the bandgap energy of the first material is represented by Eg1, and the bandgap energy of the second material is represented by Eg2. Further, the energy level difference of the valence body (Ec) between the quantum well layer 111a and the barrier layer 111b in the active layer 111 is represented by ΔEc, and the energy level difference of the valence body (Ec) between the first material and the second material is represented by ΔE. As shown in the figure, the bandgap energy Eg2 of the second material is larger than the bandgap energy Eg1 of the first material. The energy level difference ΔE of the valence body (Ec) between the first material and the second material is suitably 100 meV or more. Further, the second material is suitably a material having a thermal conductivity higher than that of the first material.

Specifically, the second material is a material different from the first material in group V (N, P, As, Sb, Bi). In the case where the first material is AlGaAs, GaAs, InGaAs, InGaP, AlInGaP, AlGaInAs, or GaInAsP, the second material can be GaN. Further, the second material may have a crystal structure different from that of the first material. For example, the crystal structure of the first material can be a zincblende structure, and the crystal structure of the second material can be a wurtzite structure.

The first mirror 103 (see FIG. 2) is provided on the side of the semiconductor layer 101 opposite to the substrate 102, i.e., on the side of the first main surface 101a, and reflects light of the wavelength λ. As shown in FIG. 2, the first mirror 103 has a first main surface 103a and a second main surface 103b. The first main surface 103a is a main surface opposite to the semiconductor layer 101, and the second main surface 103b is a main surface on the side of the semiconductor layer 101. As shown in FIG. 2, the first mirror 103 can be a DBR (Distributed Bragg Reflector) obtained by alternately stacking a low-refractive index layer 131 and a high-refractive index layer 132. This DBR can be a dielectric DBR formed of a dielectric or a semiconductor DBR formed of a semiconductor. Further, the first mirror 103 may be a metal mirror or a diffraction grating instead of the DBR.

The second mirror 104 (see FIG. 2) is provided on the side of the substrate 102 opposite to the semiconductor layer 101, i.e., on the second main surface 102b, and reflects light of the wavelength λ. As shown in FIG. 2, the second mirror 104 has a first main surface 104a and a second main surface 104b. The first main surface 104a is a main surface on the side of the substrate 102, and the second main surface 104b is a main surface opposite to the first main surface 104a. The second main surface 102b of the substrate 102 is formed in a curved surface shape by the lens 102c, and the second mirror 104 is a concave mirror where the first main surface 104a is a concave surface.

As shown in FIG. 2, the second mirror 104 can be a DBR obtained by alternately stacking a low-refractive index layer 141 and a high-refractive index layer 142. This DBR can be a dielectric DBR formed of a dielectric or a semiconductor DBR formed of a semiconductor. Further, the second mirror 104 may be a metal mirror or a diffraction grating instead of the DBR.

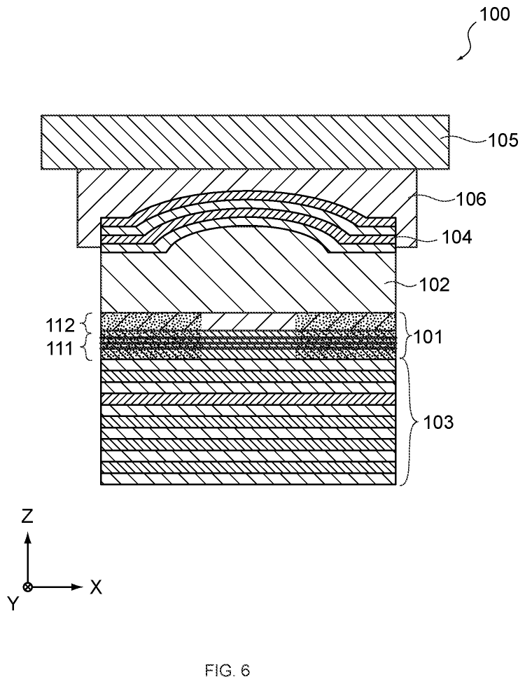

The VCSEL device 100 has the configuration as described above. Note that in the VCSEL device 100, the side of the first mirror 103 can be p-type, and the side of the second mirror 104 can be n-type. Further, the side of the first mirror 103 may be n-type, and the side of the second mirror 104 may be p-type. Further, the VCSEL device 100 may be supported by a support substrate. FIG. 6 is a cross-sectional view showing the VCSEL device 100 supported by a support substrate 105. As shown in the figure, the second mirror 104 is bonded to the support substrate 105 via an adhesive layer 106 such as wax, and the VCSEL device 100 is supported by the support substrate 105. Further, in the VCSEL device 100, the side of the first mirror 103 may be bonded to the support substrate 105.

### [Operation of VCSEL Device]

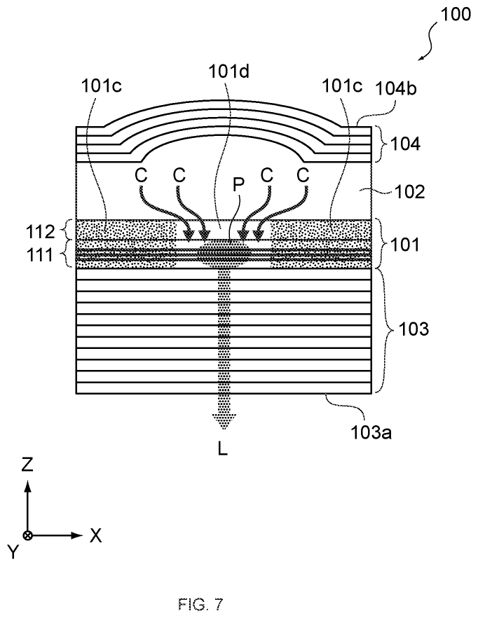

An operation of the VCSEL device 100 will be described. FIG. 7 is a schematic diagram showing an operation of the VCSEL device 100. When a voltage is applied to the VCSEL device 100, a current (“C” in FIG. 7) passes through the semiconductor layer 101. Since the ion implantation region 101c is insulated, the current is injected into the non-ion-implantation region 101d. This injected current generates spontaneous emission light (“P” in FIG. 7) by carrier recombination in the non-ion-implantation region 101d of the active layer 111. Spontaneous emission light F travels in the stacking direction of the VCSEL device 100 (Z direction), is transmitted through the semiconductor layer 101 and the substrate 102, and is reflected by the first mirror 103 and the second mirror 104.

Since the first mirror 103 and the second mirror 104 are configured to reflect light having the wavelength λ, a component of the wavelength λ, of the spontaneous emission light, forms a standing wave between the first mirror 103 and the second mirror 104, and is amplified by the active layer 111. When the injected current exceeds a threshold value, light forming a standing wave generates laser oscillation. Laser light generated thereby (“L” in FIG. 7) is transmitted through the first mirror 103, and is emitted from the first main surface 103a. Here, since a concave mirror is formed on the second mirror 104, the light reflected by the second mirror 104 is collected on (light confinement) the non-ion-implantation region 101d of the active layer 111, and diffraction loss due to optical field confinement in the layer surface direction is suppressed. Note that the VCSEL device 100 may be configured such that laser light is transmitted through the second mirror 104 and is emitted from the second main surface 104b.

### [Effects of VCSEL Device]

Effects of the VCSEL device 100 will be described. In general, in a VCSEL device, when carrier overflow from an active layer occurs, the output of laser light decreases. In particular, when the energy level difference (ΔEc in FIG. 5) between a quantum well layer and a barrier layer in the active layer is small, carrier overflow is likely to occur at high temperatures. For example, in an active layer whose crystal is capable of growing on a GaAs substrate and emits red light, the energy level difference ΔEc is as small as approximately 100 meV, and carrier overflow at high temperatures becomes a problem. Further, when the heat dissipation of the VCSEL device is small, the VCSEL device becomes high temperature, which causes carrier overflow.

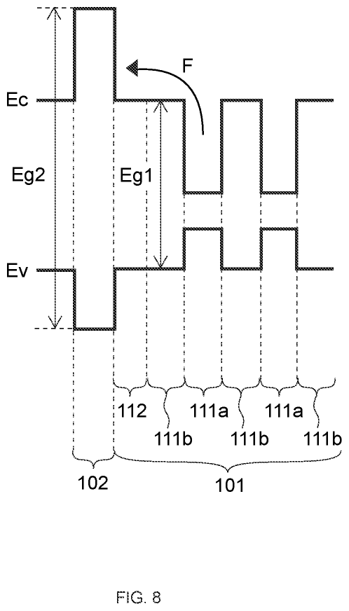

Here, in the VCSEL device 100, the substrate 102 having high bandgap energy is bonded to the semiconductor layer 101, and the substrate 102 suppresses carrier overflow. FIG. 8 is a schematic diagram showing suppression of carrier overflow by the substrate 102. As shown in the figure, since the substrate 102 has the high bandgap energy Eg2, outflow of carriers from the active layer 111 (arrow “F” in the figure), i.e., carrier overflow, is suppressed. This prevents output of laser light from decreasing at high temperatures and improves high-temperature properties.

Further, by making the substrate 102 formed of a material having a high thermal conductivity, the heat of the semiconductor layer 101 is dissipated via the substrate 102. This prevents the temperature of the semiconductor layer 101 from increasing, and carrier overflow can also be suppressed from this point of view. Therefore, it is possible to further improve the high-temperature properties of the VCSEL device 100.

### [Example of Calculating Band Alignment]

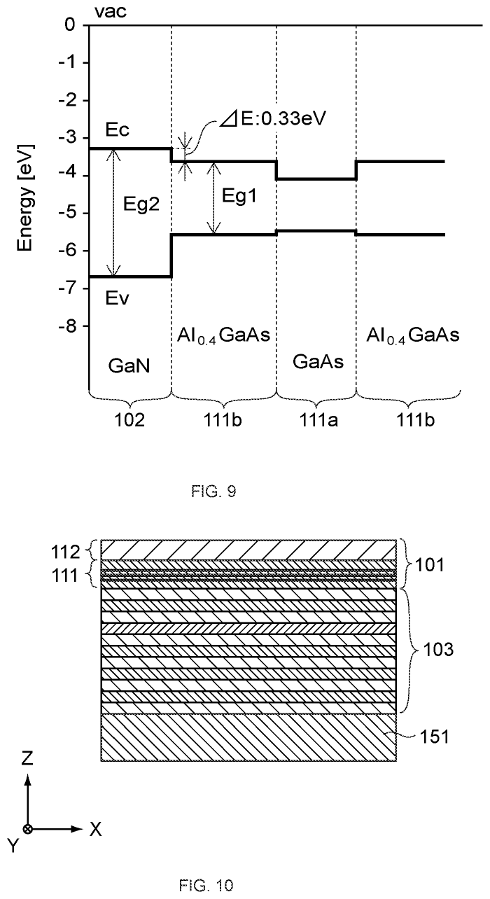

FIG. 9 shows an example of calculating band alignment in the VCSEL device 100. Calculation was made assuming that the substrate 102 is formed of GaN, the quantum well layer 111a is formed of GaAs, and the barrier layer 111b is formed of Al_{0.4}GaAs. The energy level difference ΔE between the first material (Al_{0.4}GaAs) and the second material (GaN) is as larger as 330 meV, and carrier overflow can be suppressed by combining GaN and GaAs.

### [Method of Producing VCSEL Device]

A method of producing the VCSEL device 100 will be described.

### (Production Method 1)

FIGS. 10 to 16 are each a schematic diagram showing a method 1 of producing the VCSEL device 100. As shown in FIG. 10, the first mirror 103 and the semiconductor layer 101 are formed on a substrate 151. The substrate 151 is a substrate that allows crystals of the first mirror 103 and the semiconductor layer 101 to grow, and is formed of GaAs. Subsequently, ions are implanted into the outer periphery portion of the semiconductor layer 101 to form the ion implantation region 101c and the non-ion-implantation region 101d as shown in FIG. 11.

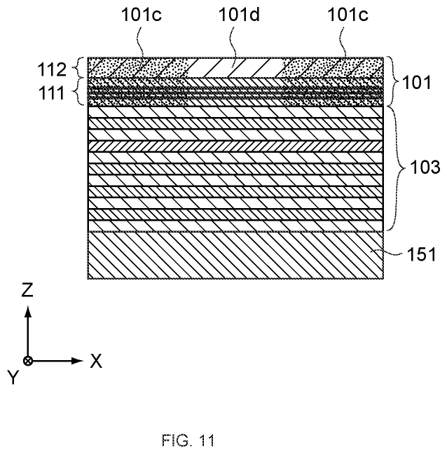

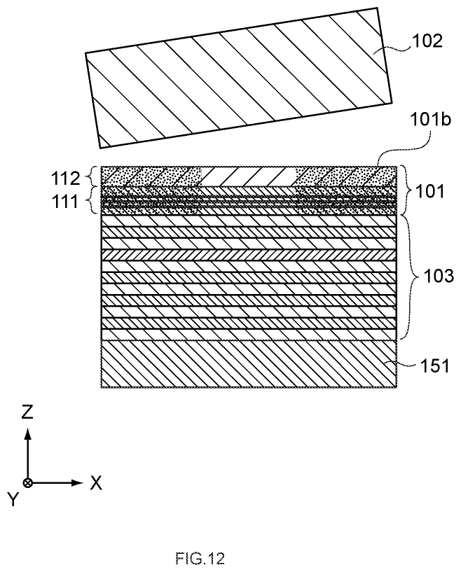

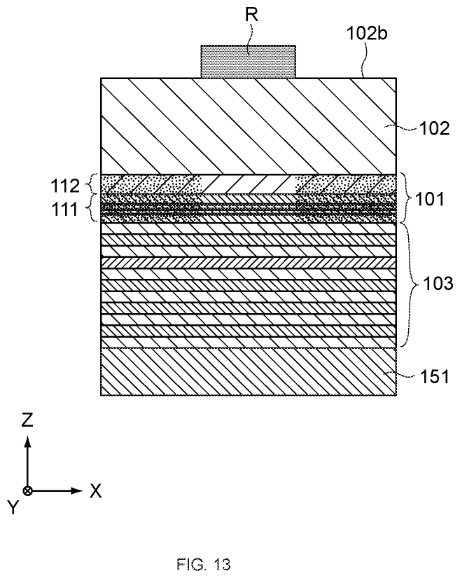

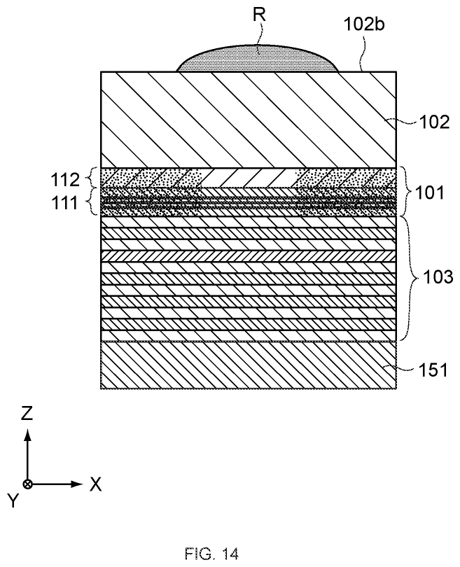

Subsequently, as shown in FIG. 12, the substrate 102 is bonded to the second main surface 101b of the semiconductor layer 101. The bonding of the substrate 102 can be performed by surface activated bonding or adhesion. As the adhesive material, a transparent conductive material such as ITO (Indium Tin Oxide) can be used. Subsequently, as shown in FIG. 13, a patterned resist layer R is formed on the second main surface 102b of the substrate 102. The resist layer R is formed of a photoresist, and can be patterned by photolithography. Subsequently, the resist layer R is heated. This causes the resist layer R to flow to form a lens shape as shown in FIG. 14.

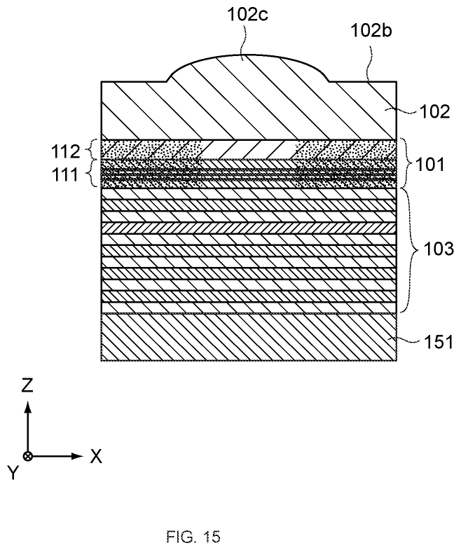

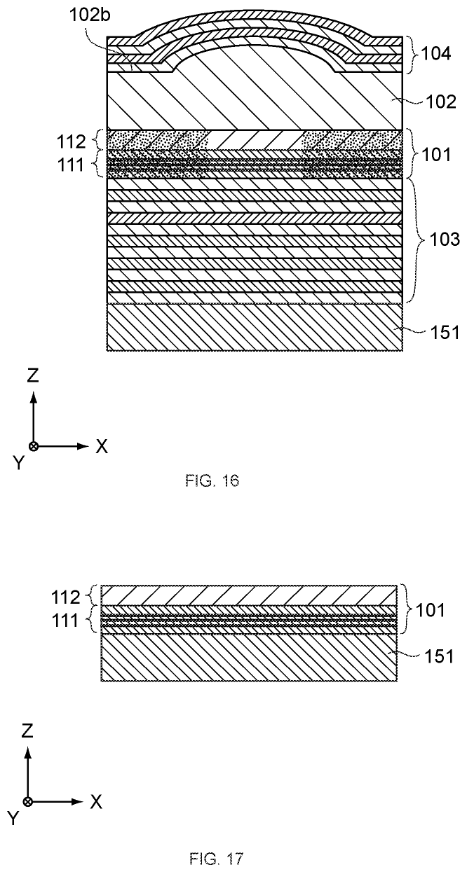

Subsequently, the substrate 102 is etched using the resist layer R having a lens shape as an etching mask to form the lens 102c as shown in FIG. 15. Note that the resist layer R having a lens shape can also be used as the lens 102c as it is without etching the substrate 102. Subsequently, as shown in FIG. 16, the second mirror 104 is formed on the second main surface 102b of the substrate 102. Finally, the substrate 151 is removed by etching or the like to prepare the VCSEL device 100 (see FIG. 1). Note that before removing the substrate 151, the second mirror 104 may be bonded to the support substrate 105 via the adhesive layer 106 (see FIG. 6) and then the substrate 151 may be removed.

In this production method, since the substrate 102 is bonded to the semiconductor layer 101, the semiconductor layer 101 and the substrate 102 may have different crystal structures. Specifically, the semiconductor layer 101 may have a zincblende structure such as GaAs, and the substrate 102 may have a wurtzite structure such as GaN.

### (Production Method 2)

FIGS. 17 to 21 are each a schematic diagram showing a method 2 of producing the VCSEL device 100. As shown in FIG. 17, the semiconductor layer 101 is formed on the substrate 151. The substrate 151 is a substrate that allows crystal of the semiconductor layer 101 to grow, and is formed of GaAs. Subsequently, ions are implanted into the outer periphery portion of the semiconductor layer 101 to form the ion implantation region 101c and the non-ion-implantation region 101d as shown in FIG. 18.

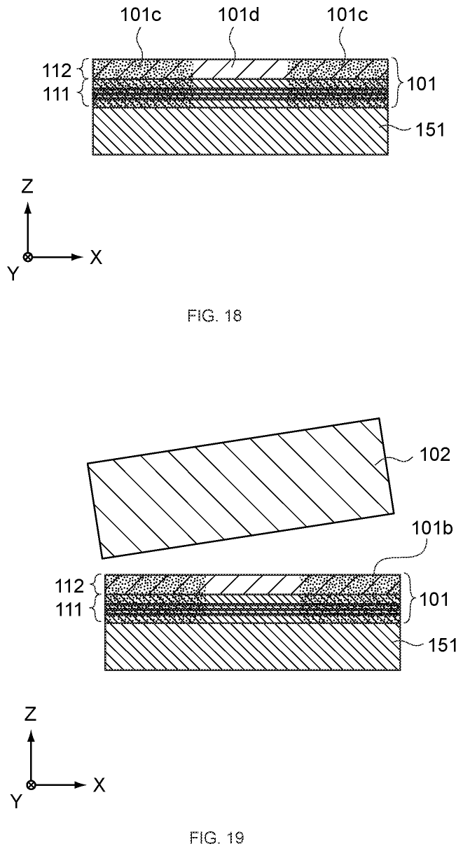

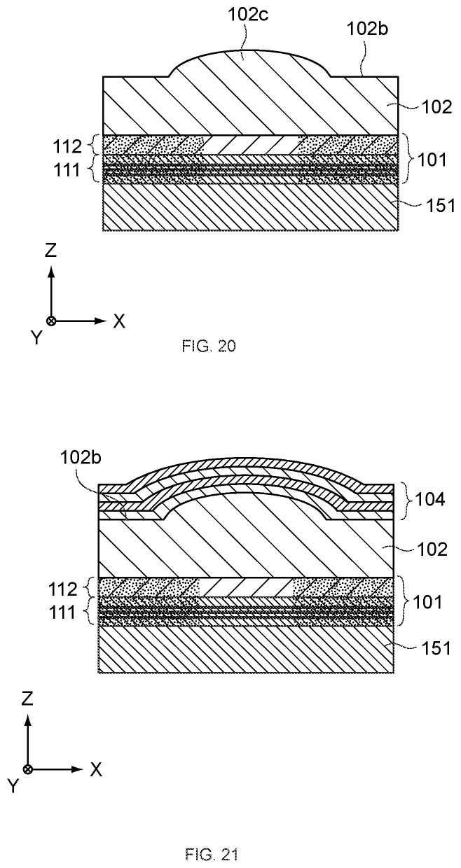

Subsequently, as shown in FIG. 19, the substrate 102 is bonded to the second main surface 101b of the semiconductor layer 101. The bonding of the substrate 102 can be performed by surface activated bonding or adhesion. As the adhesive material, a transparent conductive material such as ITO can be used. Subsequently, as shown in FIG. 20, the lens 102c is formed on the substrate 102. The lens 102c can be formed by a method similar to that in the production method 1.

Subsequently, as shown in FIG. 21, the second mirror 104 is formed on the second main surface 102b of the substrate 102. Finally, the substrate 151 is removed by etching or the like and the first mirror 103 is formed to prepare the VCSEL device 100 (see FIG. 1). Note that the second mirror 104 may be bonded to the support substrate 105 via the adhesive layer 106 (see FIG. 6) before removing the substrate 151, and then the substrate 151 may be removed.

Also in this production method, since the substrate 102 is bonded to the semiconductor layer 101, the semiconductor layer 101 and the substrate 102 can have different crystal structures.

### (Production Method 3)

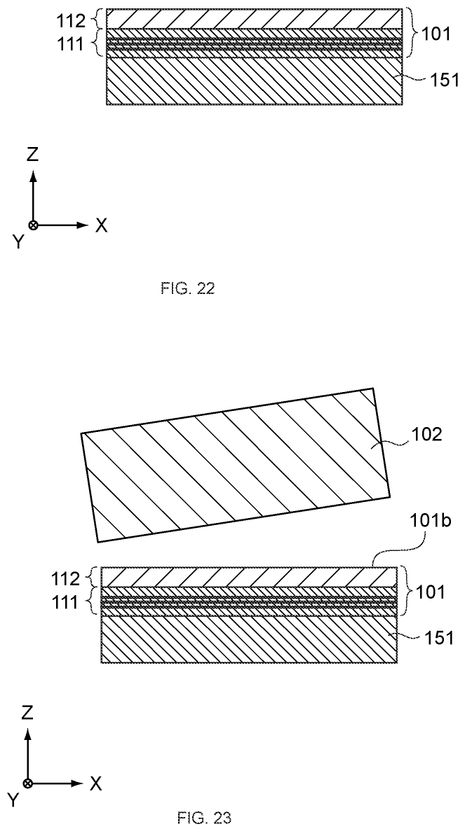

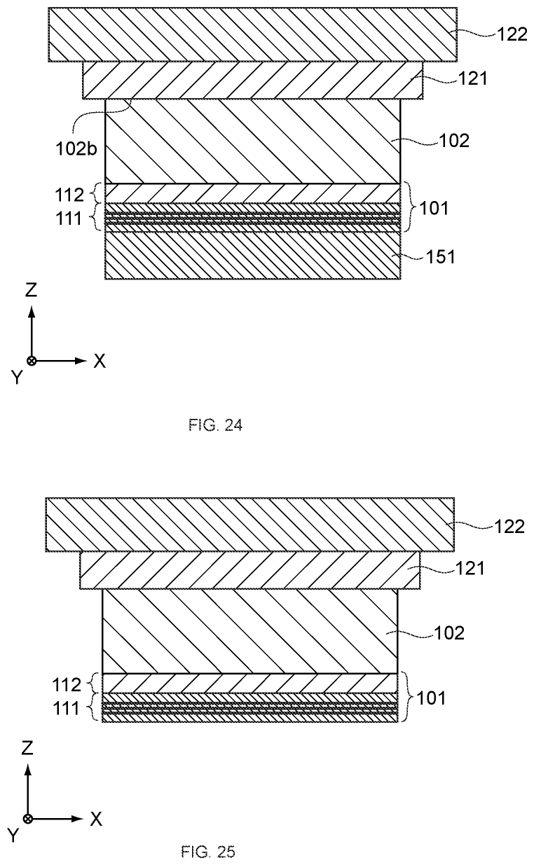

FIGS. 22 to 31 are each a schematic diagram showing a method 3 of producing the VCSEL device 100. As shown in FIG. 22, the semiconductor layer 101 is formed on the substrate 151. The substrate 151 is a substrate that allows crystal of the semiconductor layer 101 to grow, and is formed of GaAs. Subsequently, as shown in FIG. 23, the substrate 102 is bonded to the second main surface 101b of the semiconductor layer 101. The bonding of the substrate 102 can be performed by surface activated bonding or adhesion. As the adhesive material, a transparent conductive material such as ITO can be used. Subsequently, as shown in FIG. 24, a support substrate 122 is bonded to the second main surface 102b of the substrate 102 using an adhesive layer 121 such as wax. Subsequently, as shown in FIG. 25, the substrate 151 is removed by etching or the like.

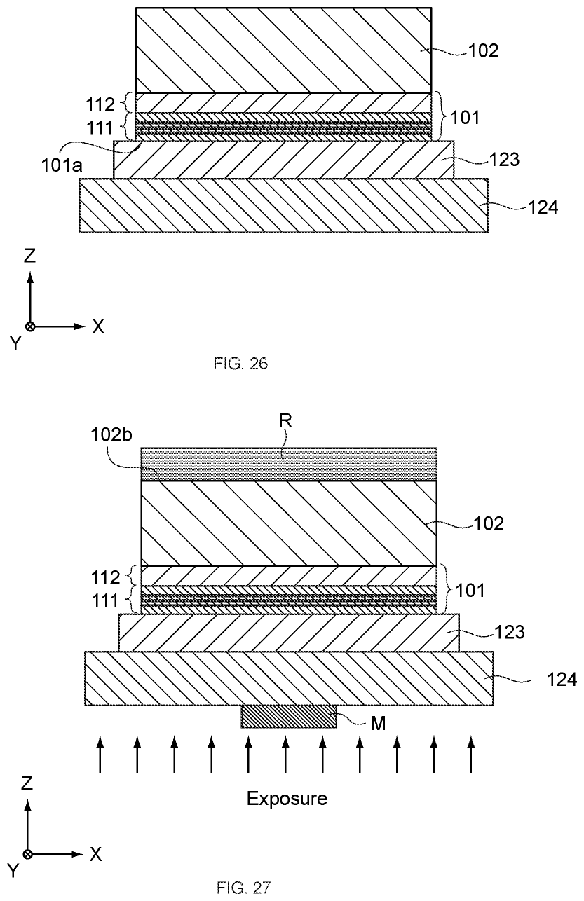

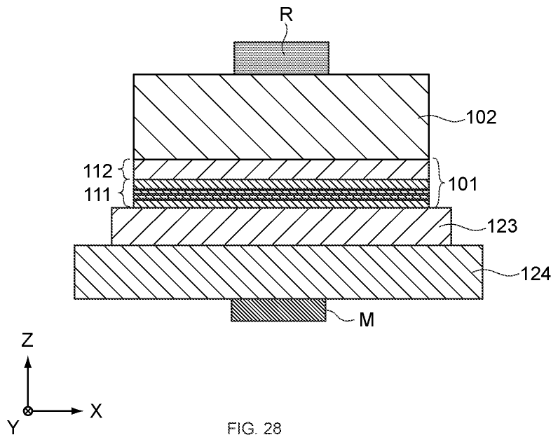

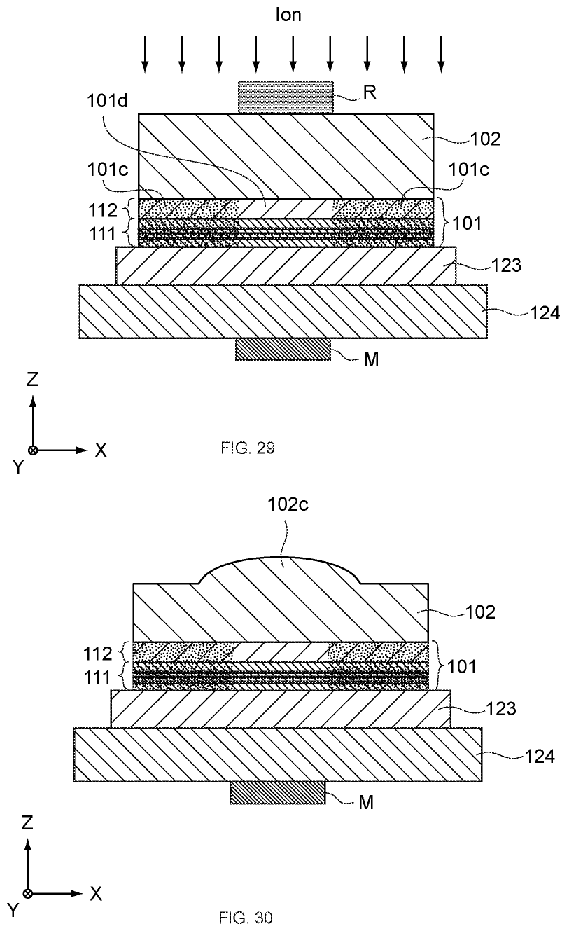

Subsequently, as shown in FIG. 26, a support substrate 124 is bonded to the first main surface 101a of the semiconductor layer 101 using an adhesive layer 123 such as wax. The support substrate 124 is a substrate that is transparent to the exposure wavelength in the next process. Further, the adhesive layer 121 and the support substrate 122 are removed. Subsequently, as shown in FIG. 27, the resist layer R formed of a photoresist is formed on the second main surface 102b of the semiconductor layer 101. Further, a patterned mask M is formed on the support substrate 124. Subsequently, light having the above exposure wavelength is applied onto the mask M to perform exposure. The region of the resist layer R that is not shielded from light by the mask M is denatured, and the solubility is improved. Subsequently, the denatured region of the resist layer R is removed to form the patterned resist layer R as shown in FIG. 28.

Subsequently, as shown in FIG. 29, ions are implanted from above the resist layer R. Ions are implanted into the region of the semiconductor layer 101 that is not shielded from ions by the resist layer R, thereby forming the ion implantation region 101c. Meanwhile, ions are not implanted into the region of the semiconductor layer 101 that is shielded from ions by the resist layer R, thereby forming the non-ion-implantation region 101d. Subsequently, as shown in FIG. 30, the lens 102c is formed on the substrate 102. The lens 102c can be formed using the resist layer R by a method similar to that in the production method 1.

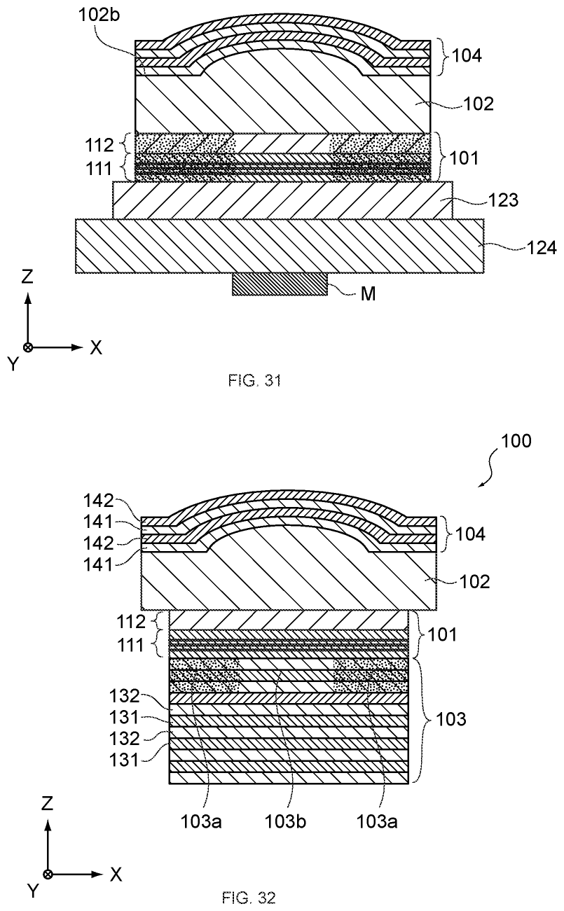

Subsequently, as shown in FIG. 31, the second mirror 104 is formed on the second main surface 102b of the substrate 102. Finally, the adhesive layer 123 and the support substrate 124 are removed and the first mirror 103 is formed to prepare the VCSEL device 100 (see FIG. 1). Note that the second mirror 104 may be bonded to the support substrate 105 via the adhesive layer 106 (see FIG. 6) before removing the support substrate 124 and the like, and then, the support substrate 124 and the like may be removed.

Also in this production method, since the substrate 102 is bonded to the semiconductor layer 101, the semiconductor layer 101 and the substrate 102 can have different crystal structures. Further, in this production method, the same resist layer R is used to perform ion implantation (see FIG. 29) and form a lens (see FIG. 30). For this reason, positional deviation between the non-ion-implantation region 101d and the lens 102c does not occur, i.e., positional deviation between current confinement and light confinement does not occur, it is possible to reduce loss in the VCSEL device 100.

### Modified Examples

Although the VCSEL device 100 has a current confinement structure formed by ion implantation in the above description, the VCSEL device 100 may have another current confinement structure. FIG. 32 is a cross-sectional view of the VCSEL device 100 having a current confinement structure formed by oxidation. As shown in the figure, this VCSEL device 100 has an oxidized region 103c and a non-oxidized region 103d formed in the first mirror 103.

The oxidized region 103c is a region of the first mirror 103 where the constituent material is oxidized, and is insulated by oxidation. The oxidized region 103c is provided on the outer periphery side of the first mirror 103, and surrounds the non-oxidized region 103d in the layer surface direction (X-Y direction). The non-oxidized region 103d is a region of the first mirror 103 where the constituent material is not oxidized, is provided on the inner peripheral side of the first mirror 103, and is surrounded by the oxidized region 103c in the layer surface direction (X-Y direction).

A current flowing through the semiconductor layer 101 and the first mirror 103 cannot pass through the oxidized region 103c and concentrates on the non-oxidized region 103d. That is, the oxidized region 103c and the non-oxidized region 103d form a current confinement structure. Note that an oxidized region and a non-oxidized region may be provided in the semiconductor layer 101. In addition, the VCSEL device 100 may have a current confinement structure using a buried tunnel junction in which a tunnel junction layer that causes a current to be transmitted therethrough is buried in the inner peripheral region in the layer surface direction (X-Y direction).

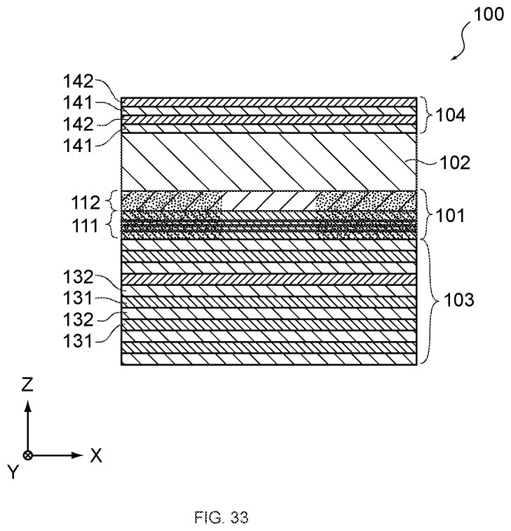

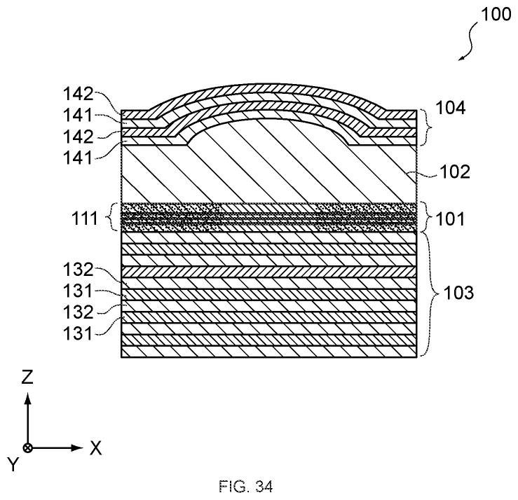

Further, although the second mirror 104 is a concave mirror in the VCSEL device 100 in the above, the present technology is not limited thereto. FIG. 33 shows a cross section of the VCSEL device 100 in which the second mirror 104 is not a concave mirror. As shown in the figure, the substrate 102 does not necessarily need to include the lens 102c, and the second mirror 104 may be a mirror having a planar shape.

Further, the semiconductor layer 101 includes the active layer 111 and the spacer layer 112 in the VCSEL device 100 in the above, the semiconductor layer 101 may include only the active layer 111. FIG. 34 is a cross-sectional view of the VCSEL device 100 in which the semiconductor layer 101 includes only the active layer 111. As shown in the figure, the substrate 102 may be bonded to the active layer 111.

### [Regarding VCSEL Device Array]

The VCSEL device 100 according to this embodiment is capable of constituting a VCSEL device array in which a plurality of VCSEL devices 100 is arrayed. This VCSEL device array includes a common electrode, and can be a simultaneous light-emitting VCSEL device array in which the plurality of VCSEL devices 100 simultaneously emits light. Further, the VCSEL device array may include independent electrodes, and can be an independently driven VCSEL device array capable of causing the individual VCSEL devices 100 to emit light individually.

### Regarding Present Disclosure

The effects described in the present disclosure are merely examples and are not limited, and additional effects may be exerted. The description of the plurality of effects described above does not necessarily mean that these effects are exhibited simultaneously. It means that at least one of the effects described above can be achieved in accordance with the conditions or the like, and there is a possibility that an effect that is not described in the present disclosure is exerted. Further, at least two feature portions of the feature portions described in the present disclosure may be arbitrarily combined with each other.

It should be noted that the present technology may also take the following configurations.
(1) A vertical cavity surface emitting laser device, including:
   a semiconductor layer that includes an active layer formed of a first material;
   a substrate that is bonded to the semiconductor layer, is formed of a second material having bandgap energy higher than that of the first material, and causes light of a specific wavelength to be transmitted therethrough;
   a first mirror that is provided on a side of the semiconductor layer opposite to the substrate, and reflects the light of a wavelength; and
   a second mirror that is provided on a side of the substrate opposite to the semiconductor layer, and causes the light of a wavelength to be transmitted therethrough.
(2) The vertical cavity surface emitting laser device according to (1) above, in which
   the second material is a material different from the first material in group V.
(3) The vertical cavity surface emitting laser device according to (2) above, in which
   the first material is AlGaAs, GaAs, InGaAs, InGaP, AlInGaP, AlGaInAs, or GaInAsP.
(4) The vertical cavity surface emitting laser device according to (3) above, in which
   the second material is GaN.
(5) The vertical cavity surface emitting laser device according to any one of (1) to (4) above, in which
   the second material is a material having a thermal conductivity higher than that of the first material.
(6) The vertical cavity surface emitting laser device according to any one of (1) to (5) above, in which
   an energy level difference between the first material and the second material is 100 meV or more.
(7) The vertical cavity surface emitting laser device according to any one of (1) to (6) above, in which
   the first material and the second material have different crystal structure.
(8) The vertical cavity surface emitting laser device according to any one of (1) to (7) above, in which
   the second mirror is a concave mirror whose surface on a side of the substrate is a concave surface.
(9) The vertical cavity surface emitting laser device according to any one of (1) to (8) above, which has
   a current confinement structure formed by ion implantation, oxidation confinement, or a buried tunnel junction.
(10) The vertical cavity surface emitting laser device according to any one of (1) to (9) above, in which
   the semiconductor layer further includes a spacer layer located between the active layer and the substrate, and
   a thickness of the spacer layer is 10 nm or more and 1000 nm or less.
(11) The vertical cavity surface emitting laser device according to any one of (1) to (10) above, in which
   the first mirror and the second mirror are each a DBR (Distributed Bragg Reflector), a metal mirror, or a diffraction grating.
(12) The vertical cavity surface emitting laser device according to (11) above, in which
   the DBR is a dielectric DBR formed of a dielectric or a semiconductor DBR formed of a semiconductor.
(13) The vertical cavity surface emitting laser device according to any one of (1) to (12) above, in which
   laser light is transmitted through the first mirror or the second mirror and emitted.
(14) A vertical cavity surface emitting laser device array in which a plurality of vertical cavity surface emitting laser devices is arrayed, each of the vertical cavity surface emitting laser device including
   a semiconductor layer that includes an active layer formed of a first material;
   a substrate that is bonded to the semiconductor layer, is formed of a second material having bandgap energy higher than that of the first material, and causes light of a specific wavelength to be transmitted therethrough;
   a first mirror that is provided on a side of the semiconductor layer opposite to the substrate, and reflects the light of a wavelength; and
   a second mirror that is provided on a side of the substrate opposite to the semiconductor layer, and causes the light of a wavelength to be transmitted therethrough.
(15) A method of producing a vertical cavity surface emitting laser device, including:
   bonding a semiconductor layer that includes an active layer formed of a first material and a substrate that is formed of a second material having bandgap energy higher than that of the first material and causes light of a specific wavelength to be transmitted therethrough to each other to form a structure including the semiconductor layer, the substrate, a first mirror that is provided on a side of the semiconductor layer opposite to the substrate and reflects the light of a wavelength, and a second mirror that is provided on a side of the substrate opposite to the semiconductor layer and causes the light of a wavelength to be transmitted therethrough.

### REFERENCE SIGNS LIST

100 VCSEL device
101 semiconductor layer
102 substrate
103 first mirror
104 second mirror
105 support substrate
106 adhesive layer
111 active layer
112 spacer layer

1. A vertical cavity surface emitting laser device, comprising:
a semiconductor layer that includes an active layer formed of a first material;
a substrate that is bonded to the semiconductor layer, is formed of a second material having bandgap energy higher than that of the first material, and causes light of a specific wavelength to be transmitted therethrough;
a first mirror that is provided on a side of the semiconductor layer opposite to the substrate, and reflects the light of a wavelength; and
a second mirror that is provided on a side of the substrate opposite to the semiconductor layer, and causes the light of a wavelength to be transmitted therethrough.

2. The vertical cavity surface emitting laser device according to claim 1, wherein
the second material is a material different from the first material in group V.

3. The vertical cavity surface emitting laser device according to claim 2, wherein
the first material is AlGaAs, GaAs, InGaAs, InGaP, AlInGaP, AlGaInAs, or GaInAsP.

4. The vertical cavity surface emitting laser device according to claim 3, wherein
the second material is GaN.

5. The vertical cavity surface emitting laser device according to claim 1, wherein
the second material is a material having a thermal conductivity higher than that of the first material.

6. The vertical cavity surface emitting laser device according to claim 1, wherein
an energy level difference between the first material and the second material is 100 meV or more.

7. The vertical cavity surface emitting laser device according to claim 1, wherein
the first material and the second material have different crystal structure.

8. The vertical cavity surface emitting laser device according to claim 1, wherein
the second mirror is a concave mirror whose surface on a side of the substrate is a concave surface.

9. The vertical cavity surface emitting laser device according to claim 1, which has
a current confinement structure formed by ion implantation, oxidation confinement, or a buried tunnel junction.

10. The vertical cavity surface emitting laser device according to claim 1, wherein
the semiconductor layer further includes a spacer layer located between the active layer and the substrate, and
a thickness of the spacer layer is 10 nm or more and 1000 nm or less.

11. The vertical cavity surface emitting laser device according to claim 1, wherein
the first mirror and the second mirror are each a DBR (Distributed Bragg Reflector), a metal mirror, or a diffraction grating.

12. The vertical cavity surface emitting laser device according to claim 11, wherein
the DBR is a dielectric DBR formed of a dielectric or a semiconductor DBR formed of a semiconductor.

13. The vertical cavity surface emitting laser device according to claim 1, wherein
laser light is transmitted through the first mirror or the second mirror and emitted.

14. A vertical cavity surface emitting laser device array in which a plurality of vertical cavity surface emitting laser devices is arrayed, each of the vertical cavity surface emitting laser device including
a semiconductor layer that includes an active layer formed of a first material;
a substrate that is bonded to the semiconductor layer, is formed of a second material having bandgap energy higher than that of the first material, and causes light of a specific wavelength to be transmitted therethrough;
a first mirror that is provided on a side of the semiconductor layer opposite to the substrate, and reflects the light of a wavelength; and
a second mirror that is provided on a side of the substrate opposite to the semiconductor layer, and causes the light of a wavelength to be transmitted therethrough.

15. A method of producing a vertical cavity surface emitting laser device, comprising:
bonding a semiconductor layer that includes an active layer formed of a first material and a substrate that is formed of a second material having bandgap energy higher than that of the first material and causes light of a specific wavelength to be transmitted therethrough to each other to form a structure including the semiconductor layer, the substrate, a first mirror that is provided on a side of the semiconductor layer opposite to the substrate and reflects the light of a wavelength, and a second mirror that is provided on a side of the substrate opposite to the semiconductor layer and causes the light of a wavelength to be transmitted therethrough.
